(19) United States
(12) Patent Application Publication
(10) Pub. No.: US 2012/0049315 A1
(43) Pub. Date: Mar. 1, 2012

(54) Thermoelectric module and method for fabricating the same

(75) Inventors: Yong Suk Kim, Yongin-si (KR); Sung Ho Lee, Seongnam-si (KR); Yong Soo Oh, Seongnam-si (KR); Tae Kon Koo, Seoul (KR)

(73) Assignee: SAMSUNG ELECTRO-MICHANICS CO., LTD, Suwon (KR)

(21) Appl. No.: 13/137,545

(22) Filed: Aug. 24, 2011

(30) Foreign Application Priority Data
Aug. 30, 2010 (KR) 10-2010-0084157

(51) Int. Cl. H01L 31/058; H01L 31/18

(52) U.S. Cl. 257/467; 438/54; 257/E31.054

(57) ABSTRACT

The present invention provides a thermoelectric module. The thermoelectric module includes a first substrate and a second substrate opposed to each other and arranged to be separated from each other, a first electrode and a second electrode arranged in an inside surface of the first and the second substrates, respectively, a thermoelectric device inserted between the first and the second electrodes and electrically connected to the first and the second electrodes and a hybrid filler inserted between the first substrate and the second substrate and provided with a high temperature part filler adjacent to a substrate at a side of a high temperature end to absorb heat among the first substrate and the second substrate and a low temperature part filler adjacent to a substrate at a side of a low temperature end to discharge heat.

### CROSS-REFERENCE TO RELATED APPLICATIONS

This application claims the benefit of Korean Patent Application No. 10-2010-0084157 filed with the Korea Intellectual Property Office on Aug. 30, 2010, the disclosure of which is incorporated herein by reference.

### BACKGROUND OF THE INVENTION

1. Field of the Invention

The present invention relates to a thermoelectric module and a method for fabricating the same; and, more particularly to a thermoelectric module without generating cracks or corrosions therein by preventing moisture or the like from being penetrated and a method for manufacturing the same.

2. Description of the Related Art

The thermoelectric module can operate as a solid state heat pump and utilize as a cooler or a heater. Since the thermoelectric module has high reliability with a simple structure and without mechanical operational elements, it has advantages of low noise and vibration as well as miniaturization in comparison with a conventional cooler using such as a compressor.

Also, the thermoelectric module is capable of performing rapid and accurate temperature control and cooling/heating conversion with simple operation, thereby applying to a high precise cooler/thermostat, an optical element device, an optical sensor and precise electric products.

Also, since the thermoelectric module realizes cooling and heating at the same time in one module by changing the polarity of direct power, it can be effectively utilized for an air handling unit or the like. It can be utilized for the other product, for example, a compact cooling device, a cosmetic refrigerator, a wine refrigerator, a hot and cold water purifier, a cooling sheet for vehicles, semiconductor equipment and a cooling/thermostat device such as a precision thermostat chamber.

In order to fabricate such thermoelectric module, the size of device, characteristics, junction and packaging and the like become main issues. According to the design of the module and the manufacturing method, the characteristics of the thermoelectric module can be determined along with the characteristics and durability, reliability and the other environments.

The conventional thermoelectric module includes a high temperature part being a relatively high temperature by absorbing heat and a low temperature part being a relatively low temperature by discharging the heat, and the difference of thermal expansion between the high temperature part and the low temperature part due to the temperature difference between the high temperature part and the low temperature part, thereby generating problems that the deterioration difference of the thermoelectric module is generated by the difference of such thermal expansion.

And also, the difference of the thermal expansion between the high temperature part and the low temperature part generates the delamination by causing the difference between the shrink and expansion of the thermoelectric module and generates the delamination to thereby generate the problems that the crack and corrosions of the thermoelectric module are generated.

### SUMMARY OF THE INVENTION

The present invention has been proposed in order to overcome the above-described problems such as cracks and corrosions generated by the deterioration difference and moisture penetration due to the difference of thermal expansion generated by the temperature difference between the high temperature part and the low temperature part; and it is, therefore, an object of the present invention to provide a thermoelectric module and a method for fabricating the same capable of solving problems such as the cracks and corrosions generated by the deterioration difference and moisture penetration due to the difference of thermal expansion of the thermoelectric module by filling a hybrid filler made of a high temperature part filler and a low temperature part filler between a first substrate and a second substrate.

In accordance with one aspect of the present invention to achieve the object, there is provided a thermoelectric module including a first substrate and a second substrate opposed to each other and arranged to be separated from each other, a first electrode and a second electrode arranged in an inside surface of the first and the second substrates, respectively, a thermoelectric device inserted between the first and the second electrodes and electrically connected to the first and the second electrodes and a hybrid filler inserted between the first substrate and the second substrate and provided with a high temperature part filler adjacent to a substrate at a side of a high temperature end to absorb heat among the first substrate and the second substrate and a low temperature part filler adjacent to a substrate at a side of a low temperature end to discharge heat.

Herein, the hybrid filler is inserted between the first substrate and the second substrate and is coated the inside surface of the first substrate, a surface of the first electrode, a surface of the thermoelectric device, a surface of the second electrode and an inside surface of the second substrate at a predetermined thickness so as to for an empty space without completely filling between the first substrate and the second substrate.

Herein, the high temperature part filler is provided with material corresponding to the thermal expansion of a substrate at the side of the high temperature end, and the low temperature part filler is provided with material corresponding to the thermal expansion of a substrate at the side of the low temperature end.

Herein, the first and second substrates are ceramic substrates, and the material of the high temperature part filler is material obtained by mixing at least one among zirconium oxide, silicon carbide, a titanium carbide glass fiber and fiber reinforced plastic to parylene or Teflon.

And also, the first and substrate and the second substrate are ceramic substrates; and the low temperature part filler is material obtained by mixing a glass fiber to paraffin or wax.

Herein, the thermoelectric module further includes thermal grease at least one least one place among between the first substrate and the first electrode, between the second substrate and the second electrode, between the thermoelectric device and the first electrode and the thermoelectric device and the second electrode.

And also, the thermoelectric device is connected to the first and second electrodes through a solder.

In accordance with another aspect of the present invention to achieve the object, there is provided a method for fabricating a thermoelectric module including the steps of: forming a first substrate where a first electrode, a first solder layer and a thermoelectric device are arranged by being stacked, forming a second substrate where a second electrode and a second solder layer corresponding to the thermoelectric device by being stacked, arranging the second substrate on the first substrate and connecting the first substrate to the second substrate by joining the first and second electrodes to the thermoelectric device by the first and second solder layers through a reflow process and forming a hybrid filler provided with a high temperature part filler adjacent to a substrate at a side of a high temperature end to absorb heat among the first substrate and the second substrate and a low temperature part filler adjacent to a substrate at a side of a low temperature end to discharge heat.

Herein, the first substrate and the second substrate are ceramic substrates.

At this time, the step of forming the hybrid filler includes the steps of: preparing high temperature part filler material obtained by mixing at least one among zirconium oxide, silicon carbide, a titanium carbide glass fiber and fiber reinforced plastic to parylene or Teflon; preparing low temperature part filler material obtained by mixing a glass fiber to paraffin or wax; and forming the hybrid filler by filing the high temperature part filler material and the low temperature part filler material between the joined first and second substrates using a dipping method.

And also, the step of forming the hybrid filler includes the steps of: preparing high temperature part filler material obtained by mixing at least one among zirconium oxide, silicon carbide, a titanium carbide glass fiber and fiber reinforced plastic to parylene or Teflon; preparing low temperature part filler material obtained by mixing a glass fiber to paraffin or wax; and forming the hybrid filler by coating the high temperature part filler material on the inside surface of the first substrate, the surface of the first electrode and a portion of surface of the thermoelectric device and coating the low temperature part filler material on the inside surface of the second substrate, the surface of the second electrode and a portion of surface of the thermoelectric device using a impregnation method.

Herein, the method for fabricating the thermoelectric module further includes thermal grease at least one place among between the first substrate and the first electrode, between the second substrate and the second electrode, between the thermoelectric device and the first electrode and between the thermoelectric device and the second electrode.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a cross-sectional view showing a thermoelectric module in accordance with one embodiment of the present invention;

FIG. 2 is a cross-sectional view showing a thermoelectric module in accordance with another embodiment of the present invention;

FIGS. 3 to 6 are cross-sectional views showing a method for fabricating a thermoelectric module in accordance with still another embodiment of the present invention; and

FIGS. 7 and 8 are cross-sectional views showing a method for fabricating a thermoelectric module in accordance with still another embodiment of the present invention.

### DETAILED DESCRIPTION OF THE PREFERABLE EMBODIMENTS

Embodiments of the present invention will be described in detail with reference to the accompanying drawings. The embodiments described hereinafter will be provided as examples so that the scope of the invention is fully conveyed to those skilled in the art.

Therefore, this invention may be embodied in many different forms and should not be construed as limited to the exemplary embodiments set forth herein. And, in the drawings, the size and relative sizes of layers and regions may be exaggerated for clarity. Like reference numerals in the drawings denote like elements.

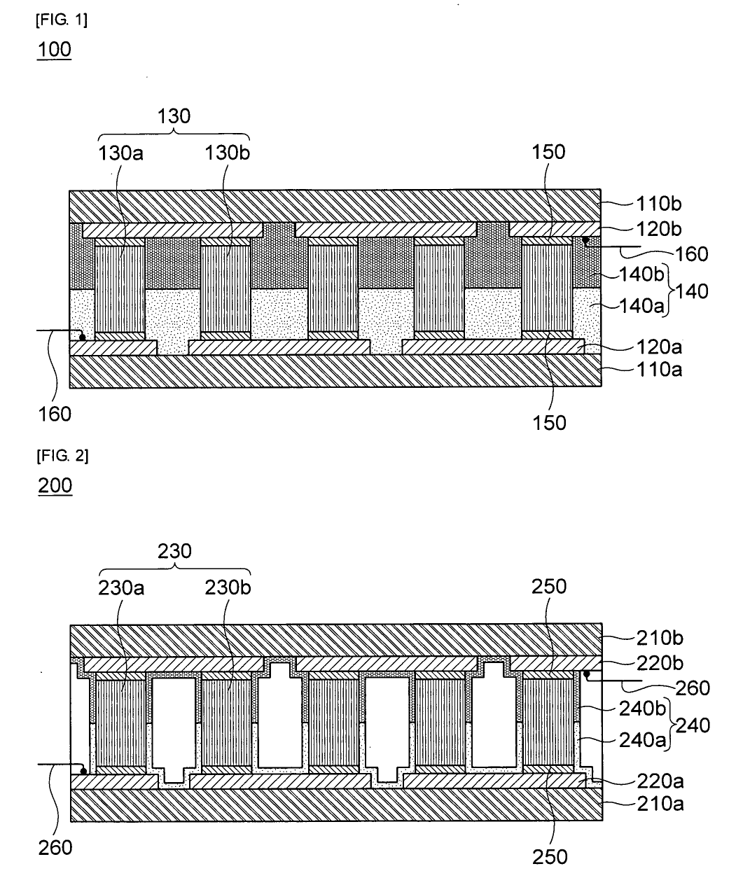

FIG. 1 is a cross-sectional view showing a thermoelectric module in accordance with one embodiment of the present invention.

Referring to FIG. 1, a thermoelectric module 100 in accordance with the present invention may include a first substrate 110a and a second substrate 110b separated with opposing to each other, a first electrode 120a and a second electrode 120b inserted inside surfaces of the first and second substrates 110a and 110b and a thermoelectric device 130 inserted between the first and second substrate 110a and 110b.

Also, the thermoelectric module 100 may include a hybrid filler 140 filed between the first and second substrates 110a and 110b.

The first and second substrates 110a and 110b may play a role of supporting the thermoelectric device 130 and the first and second electrodes 120a and 120b. Further, if the thermoelectric device 130 is formed by a plurality of pieces, the first and second substrates 110a and 110b may play a role of connecting the plurality of thermoelectric devices 130.

And also, the first substrate 110a and the second substrate 110b can play the role of absorbing heat from outside or discharging the heat to the outside through the heat exchange of the thermoelectric device 130 by being connected to an external apparatus. That is, the first substrate 110a and the second substrate 110b can play the role of performing the heat exchange between the external apparatus and the thermoelectric device 130. Therefore, the efficiency of the thermoelectric module 100 can be affected by the thermal conductivity of the first and second substrates 110a and 110b.

In order to this, the first and second substrates 110a and 110b can be made of ceramic having high thermal conductivity.

Also, the first and second substrates 110a and 110b can be made of metal having excellent thermal conductivity. For example, the first and second substrates 110a and 110b can be made of aluminum and copper or the like. In this result, the thermoelectric efficiency can be improved by allowing the first and second substrates 110a and 110b to have excellent thermal conductivity.

At this time, between the inside surfaces of the first substrate 110a and the second substrate 110b, specifically between the first substrate 110a and the first electrode 120a and between the second substrate 110b and the second electrode 120b, the electric insulating property of the first and second substrates 110a and 110b can be endowed by arranging the insulating layer(not shown) to insulate between the first and second substrates 110a and 110b and the first and second electrodes 120a and 120b made of metal. At this time, the insulating layer can be made of material having durability capable of withstanding the process to form the thermoelectric module 100. For example, the insulating layer can be made of any one among SiO₂, Al₂O₃, TiO₂, ZnO, NiO and Y₂O₃.

Herein, the insulating layer can be formed in a thickness ranging from 0.2 μm to 10 μm. If the thickness of the insulating layer is below 0.2 μm, it is difficult to secure the insulation property. Whereas, if the thickness of the insulating layer is above 10 μm, it can deteriorate the thermal conductivity between the first substrate 110a or the second substrate 110b and the thermoelectric device 130.

Further, the insulating layer can play a role of securing the insulation property of the first substrate 110a and the second substrate 110b as well as it can further perform a role of filling air gaps formed in the first substrate 110a and the second substrate 110b. Hereby, it can prevent the heat transmission from being deteriorated by the air gaps between the first substrate 110a and the first electrode 120a and between the second substrate 110b and the second electrode 120b.

On the other hand, the thermoelectric device 130 can include a P-type semiconductor 130a and an N-type semiconductor 130b. At this time, the P-type semiconductor 130a and the N-type semiconductor 130b can be alternatively arranged on the same plane.

At this time, the first and second electrodes 120a and 120b can be arranged to face each other with placing the thermoelectric device 130 therebetween. At this time, a pair of P-type semiconductor 130a and N-type semiconductor 130b are electrically connected by the first electrode 120a placed at the bottom surface therebelow and another pair of neighboring P-type semiconductor 130a and the N-type semiconductor 130b can be electrically connected by the second electrode 120b located on the top surface thereof.

The first electrode 120a and the second electrode 120b and the thermoelectric device 130 can be connected to each other by a solder 150. Herein, the solder 150 can include Sn such as PbSn or CuAgSn.

In addition, the first and second electrodes 120a and 120b can supply power to an external power unit or receive power by being connected to the external power unit through a wire 160. That is, if the thermoelectric module 100 plays a role of a generating apparatus, the power can be supplied to the external power unit, and if it plays a role of a cooling apparatus, the power can be received from the external power unit.

Also, not shown in the drawings, thermal grease can be inserted between interfaces between each element. For example, the thermal grease can be inserted in at least one place located between the first substrate 110a and the first electrode 120a, between the second substrate 120 and the second electrode 120b, the thermoelectric device 130 and the first electrode 120a and the thermoelectric device 130 and the second electrode 120b. Herein, the thermal grease plays the role of filling the air gaps formed in each interface, thereby playing a role to prevent the thermal conductivity from being deteriorated by the air gaps.

The hybrid filler 140 is inserted between the first substrate 110a and the second substrate 110b.

Herein, if the first substrate 110a is a side of a high temperature end to absorb heat and the second substrate 110b is a side of a low temperature end to discharge the heat, the hybrid filler 140 includes a high temperature part filler 140a adjacent to the first substrate 110a as a substrate at the side of the high temperature end to absorb the heat and a low temperature part filler 140b adjacent to the second substrate 110b as a substrate at the side of the high temperature end to discharge the heat. At this time, if the first substrate 11a is the side of the low temperature end and the second substrate 110b is the side of the high temperature end, the positions of the high temperature part filler 140a and the low temperature part 140b can be exchanged from each other.

The high temperature part filler 140a and the low temperature part filler 140b are provided to solve the problems to be generated by the difference of thermal expansion between the first substrate 110a and the second substrate 110b. That is, the first substrate 110a as the side of the high temperature end and the second substrate 110b as the low temperature end as described above have the different temperature from each other, the present invention is aimed to solve the problems to generate the deterioration difference or the cracks and corrosions to the thermoelectric module by the difference of the thermal expansion due to the different temperatures are generated.

This is achieved by allowing the high temperature filler 140a to include the material corresponding to the thermal expansion of the first substrate 110a as the side of the high temperature end and the low temperature filler 140b to include the material corresponding to the thermal expansion of the second substrate 110b as the side of the low temperature end. That is, the hybrid filler 140 is filled between the first substrate 110a and the second substrate 110b; and the high temperature part filler 140a made of the material equal to or similar to the thermal expansion of the first substrate 110a as the side of the high temperature end is filled to be adjacent to the first substrate 110a and the low temperature part 140b made of the material equal to or similar to the thermal expansion of the second substrate 110b as the side of the low temperature end is filled to be adjacent to the second substrate 110b.

At this time, if the first substrate 110a and the second substrate 110b are the ceramic substrate, the high temperature part filler 140a can be made of a material obtained by mixing at least one among zirconium oxide, silicon carbide, a titanium carbide glass fiber and fiber reinforced plastic to parylene or Teflon, and the low temperature part filler 140b can be made of a material obtained by mixing a glass fiber to paraffin or wax. Preferably, the high temperature part filler 140a may be the material obtained by mixing the fiber reinforced plastic and parylene and the low temperature part filler 140b may be the material obtained by mixing the glass fiber and the paraffin.

Meanwhile, although FIG. 1 shows that the hybrid filler 140 including the high temperature part filler 140a and the low temperature part filler 140b is filled between the inside surface of the first substrate 110a and the inside surface of the second substrate 110b, if necessary, the high temperature part filler may be included on the outside surface and four corner surfaces of the first substrate 11a, i.e., over the whole surface of the first substrate 110a, and the low temperature part filler may be included on the outside surface and four corner surfaces of the second substrate 110b, i.e., over the whole surface of the second substrate 110b. At this time, the high temperature part filler and the low temperature part filler provided on the outside surfaces and four corner surfaces of each of the first substrate 110a and the second substrate 110b can be formed at a thickness thinner in comparison with the high temperature part filler 140a and the low temperature part filler 140b provided between the inside surfaces.

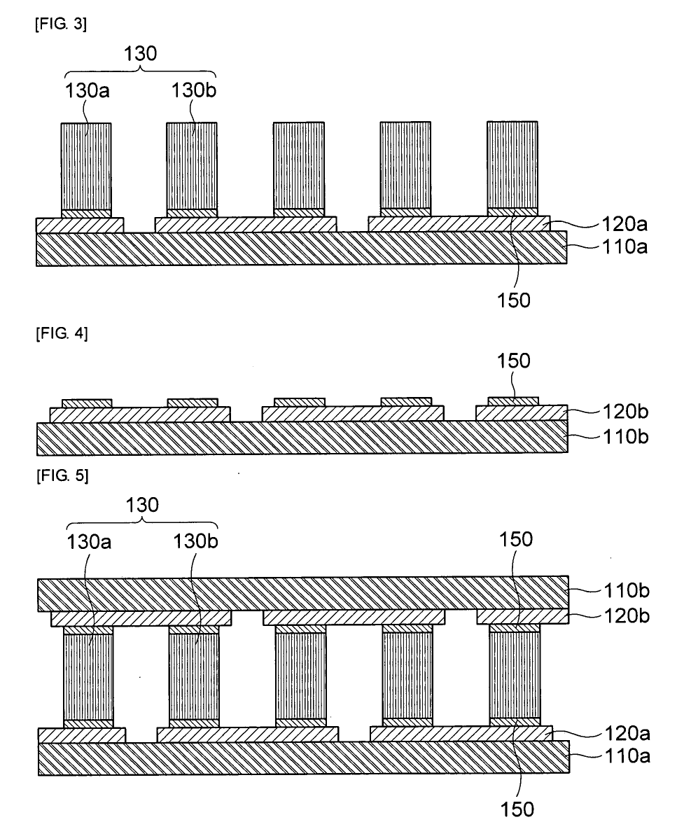

FIG. 2 is a cross-sectional view showing a thermoelectric module in accordance with another embodiment of the present invention.

Referring to FIG. 2, the thermoelectric module 200 in accordance with another embodiment of the present invention can include a first and a second substrates 210a and 210b spaced apart from each other with facing to each other, a first and a second electrodes 220a and 220b inserted between inside surfaces of the first and the second substrates 210a and 210b, respectively, and a thermoelectric device 230 inserted between the first and the second substrates 210a and 210b.

Also, the thermoelectric module 200 can include a hybrid filler 240 inserted between the first and the second substrates 210a and 210b.

Also, the thermoelectric module 200 can include a solder 250 to connect the thermoelectric device 230 to the first electrode 220a and the second electrode 220b and can include a wire 260 to connect an external power unit to the first and the second electrodes 220a and 220b.

The thermoelectric module 200 in accordance with another embodiment of the present invention is different from the thermoelectric module 100 explained with reference to FIG. 1 only in the hybrid filler 240 and the detail explanation for the other structures will be omitted since the other structures such as the first and the second substrates 210a and 210b, the first and the second electrodes 220a and 220b, the thermoelectric device 230, the solder 250, the wire 260 and the other structures are similar to the first and the second substrates 110a and 110b, the first and the second electrodes 120a and 120b, the thermoelectric device 130, the solder 150, the wire 160 and the other structures. Accordingly, only the hybrid filler 240 having the difference will be described.

The hybrid filler 240 in accordance with embodiment of the present invention is inserted between the first substrate 210a and the second substrate 220a as shown in FIG. 2, it is provided in a shape which is coated on the surface such as the inside surface of the first substrate 210a, the first electrode 220a, the thermoelectric device 230, the second electrode 220b and the inside surface of the second substrate 210b at a uniform thickness. Precisely, by being formed in a shape coated at a predetermined thickness on the exposed surfaces such as the inside surface of the first substrate 210a, the first electrode 220a, the thermoelectric device 230, the second electrode 220b and the inside surface of the second substrate 210b, there are empty spaces without incompletely filling between the thermoelectric devices 230.

At this time, the hybrid filler 240 is provided with the high temperature part filler 240a and the low temperature part filler 240b similar to the high temperature part filler 140a and the low temperature part filler 140b explained with reference to FIG. 1 and it is provided to be adjacent to the first electrode 210a as the side of the high temperature end and the second electrode 210b as the side of the low temperature end, respectively.

The detail explanations for the materials and functions of the high temperature part filler 240a and the low temperature part filler 240b of the hybrid filler 240 will be omitted, since they are similar to those of the high temperature part filler 140a and the low temperature part filler 140b described with reference to FIG. 1.

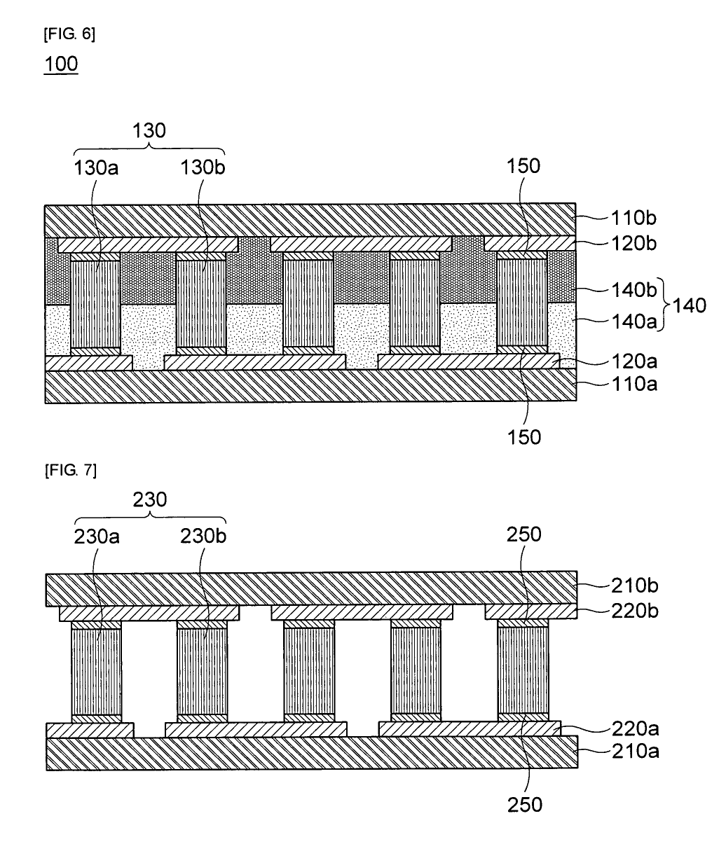

FIGS. 3 to 6 are cross-sectional views showing a method for fabricating a thermoelectric module in accordance with another embodiment of the present invention.

Referring to FIGS. 3 to 6, the method for fabricating the thermoelectric module in accordance with another embodiment of the present invention will be described in detail.

Referring to FIG. 3, in order to manufacture the thermoelectric module, a first substrate 110a is prepared at first.

The first substrate 110a may be a ceramic substrate made of ceramic.

And also, the first substrate 110a may be made of metal material having excellent thermal conductivity, if the first substrate 110a is made of the metal material, an insulating layer (not shown) can be formed on the inside surface of the first substrate 110a.

The insulating layer can be made of any one among SiO₂, Al₂O₃, TiO₂, ZnO, NiO and Y₂O₃. Herein, one example of methods for forming the insulating layer is a printing method, an ALD(Atom Layer Deposition) method, a sputtering method, an E-beam method and a CVD(Chemical Vapor Deposition) method or the like, and the insulating layer can be formed in a thickness ranging from 0.2 μm to 10 μm considering on the effect to the secured insulation and thermal conductivity.

The first electrode 120a is formed on the inside surface of the first substrate 110a. Herein, after a conductive layer is formed by depositing conductive material, the first electrode 120a can be formed by patterning the conductive layer. However, it is not limited to this in the embodiments of the present invention; for example, the first electrode 120a can be formed through a plating process and a printing process or the like.

And then, a first solder layer 150a is formed on the first electrode 120a. The first solder layer 150a can be formed by printing conductive paste including Sn such as PbSn or CuAgSn or the like.

And then, the thermoelectric device 130 is arranged on the first solder layer 150a. Herein, the thermoelectric device 130 can include a P-type semiconductor 130a and an N-type semiconductor 130b, at this time the P-type semiconductor 130a and the second surface improvement layer 130b can be exchanged alternately.

Referring to FIG. 4, the second substrate 110b is prepared independently from the processes for forming the first electrode 120a, the first solder layer 150a and the thermoelectric device 130 on the first substrate 110a, and proceeds the process to form the second electrode 120b and the second solder layer 150b on the inside surfaces of the second substrate 110b.

At this time, the second substrate 110b may be the ceramic substrate made of ceramic similar to the first substrate 110a; may be made of a metal material having excellent thermal conductivity; and, if the second substrate 110b is made of the metal material, an insulating layer (not shown) can be formed on the inside surfaces of the second substrate 110a.

The second electrode 120b and the second solder layer 150b are sequentially formed on the inside surfaces of the second substrate 110b. Herein, the insulating layer, the second electrode 120b and the second solder layer 150b can be equal to the insulating layer, the first electrode 120a and the first solder layer 150a in material and they can be formed through the same formation method.

Referring to FIG. 5, after the second substrate 110b is arranged on the first substrate 110a so as to make the thermoelectric device 130 and the second electrode 120b contact to each other, with applying a predetermined pressure to the second substrate 110b or the first substrate 110a, by connecting the thermoelectric device 130 to the first and the second electrode 120a and 120b through a reflow process, the first substrate 110a is connected to the second substrate 110b.

Referring to FIG. 6, the thermoelectric module 100 is finished by proceeding the process of filling the hybrid filler 140 between the connected first substrate 110a and the second substrate 110b.

At this time, the process of filling hybrid filler 140 proceeds the process for preparing the high temperature part filler raw material and the low temperature part filler raw material at first. The high temperature part filler raw material is prepared by mixing at least one among zirconium oxide, silicon carbide, a titanium carbide glass fiber and fiber reinforced plastic to parylene or Teflon and the low temperature part filler raw material is prepared by mixing a glass fiber to paraffin or wax. Preferably, the high temperature part filler raw material is prepared by mixing the fiber reinforced plastic and parylene and the low temperature part filler raw material is prepared by mixing the glass fiber and the paraffin.

And then, the thermoelectric module 100 in accordance with one embodiment of the present invention is formed by filling the hybrid filler 140 including the high temperature part filler 140a and the low temperature part filler 140b between the first substrate 110a and the second substrate 110b by using the low temperature part filler raw material and the high temperature part filler raw material.

At this time, although various methods can be used for filling the high temperature part filler 140a and the low temperature part filler 140b between the first substrate 110a and the second substrate 110b, they can be filled by using a representative dipping method.

That is, the low temperature part filler raw material and the high temperature part filler raw material are formed in a shape of solution or slurry, i.e., a low temperature par filler raw material solution or a high temperature part filler raw material solution is formed or a low temperature filler raw material slurry or a high temperature part filler raw material slurry is formed. And then, the second substrate 110b is immerged into the low temperature filler raw material solution or the low temperature part filler raw material slurry, the low temperature part filler 140b is formed at the side of the second substrate 110b as the side of the low temperature end by not immerging the first substrate 110a, i.e., by immerging the connected first substrate 110a and the second substrate 110b in half, and the first substrate 110a is immerged into the high temperature filler raw material solution or the high temperature part filler raw material slurry, the high temperature part filler 140a can be filled in the side of the first substrate 110a as the side of the high temperature end by immerging the remaining part of the connected first substrate 110 and the second substrate 110b.

At this time, although in the above description the low temperature part filer 140b is formed at first and the high temperature part filler 140a is formed, but after the high temperature part filler 140a is formed at first and the low temperature part filler 140b can be formed.

On the other hands, although not shown in the drawings, the high temperature part 140a can be formed at a predetermined thickness simultaneously while the high temperature part filler 140a is formed at the side of the first substrate 110a on the outside surface and four side surface of the first substrate 110a; and the low temperature part filler 140b can be formed at a predetermined thickness while the low temperature part filler 140b is formed on the outside surface and four side surfaces of the second substrate 110b.

In addition, although not shown in the drawings, thermal grease can be further formed between interfaces between each element, e.g., at least one place located between the first substrate 110a and the first electrode 120a, between the second substrate 120 and the second electrode 120b, the thermoelectric device 130 and the first electrode 120a and the thermoelectric device 130 and the second electrode 120b.

In addition, although not shown in the drawings, a process to connect a wire 160 to the first electrode 120a and the second electrode 120b may be proceeded so as to connect the wire 160 to the first electrode 120a and the second electrode 120b similar to the thermoelectric module 100 as shown in FIG. 1.

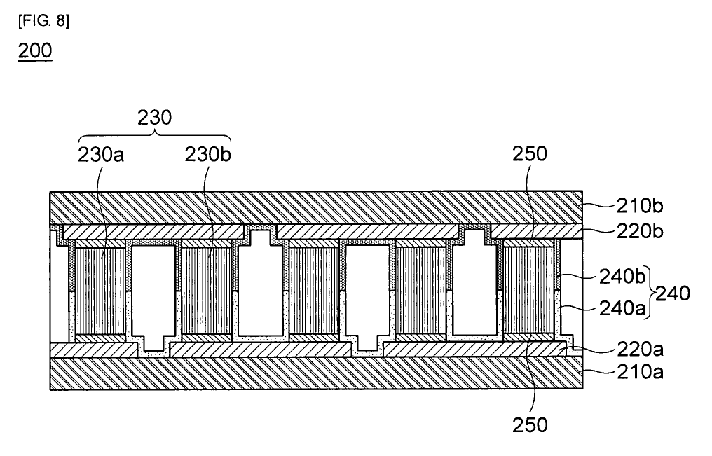

FIGS. 7 and 8 are cross-sectional views showing a method for fabricating a thermoelectric module in accordance with still another embodiment of the present invention.

Referring to FIGS. 7 and 8, the method for fabricating the thermoelectric module in accordance with still another embodiment of the present invention will be described in detail.

Referring to FIG. 7, the first substrate 110a is supplied at first as similar to the method for fabricating the thermoelectric module in accordance with one embodiment of the present invention described with reference to FIGS. 3 to 5. The first electrode 220a, the first solder layer 250a and the thermoelectric device 230 are formed on the inside surface of the first substrate 110a, sequentially. And then, the second substrate 210b is prepared; and the second electrode 220b and the second solder layer 250b are formed on the inside surfaces of the second substrate 210b, sequentially. And, after the second substrate 210b is arranged on the first substrate 210a to make the thermoelectric device 230 be contact with the second electrode 220b from each other, the first substrate 210a and the second substrate 210b are joined by connecting the first and the second electrodes 220a and 220b to the thermoelectric device 230 through a reflow process. The other detail processes and materials or the like are referred to the method for fabricating the thermoelectric module in accordance with one embodiment of the present invention described with reference to FIGS. 3 to 5.

Referring to FIG. 8, the thermoelectric module 200 is finished by proceeding a process of coating the hybrid filler 240 between the connected first substrate 210a and the second substrate 210b.

At this time, the process of coating the hybrid filler 240 proceeds a process of preparing a high temperature part filler raw material and a low temperature part filler raw material at first. At this time, since the high temperature part filler raw material and the low temperature part filler raw material can be prepared by the same materials and methods of the high temperature part filler raw material and the low temperature filler raw material described with reference to FIG. 6, the detail description thereof will be omitted.

In the embodiments of the present invention, the hybrid filler 240 can be formed by using an infiltration method.

That is, the low temperature part filler raw material and the high temperature part filler raw material are formed in the type of solution or the type of slurry, i.e., the low temperature part filler raw material solution or the high temperature part filler raw material solution is formed or the low temperature part filler raw material slurry or the high temperature part filler raw material slurry is formed. And then, the second substrate 210b is immerged into the low temperature part filler raw material solution or the low temperature part filler raw material slurry; and the low temperature part filler 240b is formed at a predetermined thickness on the inside surface of the second substrate 210b, the second electrode 220b and the surface of portion of the thermoelectric device 230 without sinking the first substrate 210a, i.e., by infiltrating after the connected first substrate 210a and the second substrate 210b are immerged in half. The first substrate 210a is immerged into the high temperature part filler raw material solution or the high temperature part filler raw material slurry; and the high temperature part filler 240a can be formed at a predetermined thickness on the inside surface of the first substrate as the side of the high temperature end, the first electrode 210b and the surface of the remaining part of the thermoelectric device 230 by immerging the remaining parts of the connected first substrate 210a and the second substrate 210b.

At this time, although the above explanation shows that the low temperature part filler 240b is coated at first and the high temperature part filler 240a is coated, but after the high temperature part filler 240a is coated at first and the low temperature part filler 240b can be coated.

Meanwhile, although not shown in the drawings, when the high temperature part filler 240a is coated at the side of the first substrate 210a on the outside surface of the first substrate 210a and four side surfaces, the high temperature part filler 240a can be coated at a predetermined thickness simultaneously; and when the low temperature part filler 240b is coated on the outside surface and four side surfaces of the second substrate 210b similarly, the low temperature part filler 240b can be formed at a predetermined thickness.

In addition, although not shown in the drawings, the thermal grease can further formed on the interfaces between each element, for example, on at least one place among between the first substrate 210a and the first electrode 220a, between the second substrate 210b and the second electrode 220b, between the thermoelectric device 230 and the first electrode 220a and the thermoelectric device 230 and the second electrode 220b.

In addition, although not shown in the drawings, in order to connect the wire 260 to each of the first electrode 220a and the second electrode 220b similar to the thermoelectric module 200 as shown in FIG. 2, a process to connect the wire 260 to the first electrode 220a and the second electrode 220b can be proceeded.

The thermoelectric modules in accordance with embodiments of the present invention and methods for fabricating the same have advantages that crack and corrosions generated by the moisture penetration due to the delamination generated by the deterioration difference due to the difference of thermal expansion and the difference of the thermal expansion are not generated.

As described above, although the preferable embodiments of the present invention have been shown and described, it will be appreciated by those skilled in the art that substitutions, modifications and variations may be made in these embodiments without departing from the principles and spirit of the general inventive concept, the scope of which is defined in the appended claims and their equivalents.

1. A thermoelectric module comprising:
a first substrate and a second substrate opposed to each other and arranged to be separated from each other;
a first electrode and a second electrode arranged in an inside surface of the first and the second substrates, respectively;
a thermoelectric device inserted between the first and the second electrodes and electrically connected to the first and the second electrodes; and
a hybrid filler inserted between the first substrate and the second substrate and provided with a high temperature part filler adjacent to a substrate at a side of a high temperature end to absorb heat among the first substrate and the second substrate and a low temperature part filler adjacent to a substrate at a side of a low temperature end to discharge heat.

2. The thermoelectric module of claim 1, wherein the hybrid filler is inserted between the first substrate and the second substrate and is coated the inside surface of the first substrate, a surface of the first electrode, a surface of the thermoelectric device, a surface of the second electrode and an inside surface of the second substrate at a predetermined thickness so as to for an empty space without completely filling between the first substrate and the second substrate.

3. The thermoelectric module of claim 1, wherein the high temperature part filler is provided with material corresponding to the thermal expansion of a substrate at the side of the high temperature end, and
the low temperature part filler is provided with material corresponding to the thermal expansion of a substrate at the side of the low temperature end.

4. The thermoelectric module of claim 3, wherein the first and second substrates are ceramic substrates, and
the material of the high temperature part filler is material obtained by mixing at least one among zirconium oxide, silicon carbide, a titanium carbide glass fiber and fiber reinforced plastic to parylene or Teflon.

5. The thermoelectric module of claim 3, wherein the first and substrate and the second substrate are ceramic substrates; and
the low temperature part filler is material obtained by mixing a glass fiber to paraffin or wax.

6. The thermoelectric module of claim 1, further comprising thermal grease at least one place among between the first substrate and the first electrode, between the second substrate and the second electrode, between the thermoelectric device and the first electrode and the thermoelectric device and the second electrode.

7. The thermoelectric module of claim 1, wherein the thermoelectric device is connected to the first and second electrodes through a solder.

8. A method for fabricating a thermoelectric module comprising:
forming a first substrate where a first electrode, a first solder layer and a thermoelectric device are arranged by being stacked;
forming a second substrate where a second electrode and a second solder layer corresponding to the thermoelectric device by being stacked;
arranging the second substrate on the first substrate and connecting the first substrate to the second substrate by joining the first and second electrodes to the thermoelectric device by the first and second solder layers through a reflow process; and
forming a hybrid filler provided with a high temperature part filler adjacent to a substrate at a side of a high temperature end to absorb heat among the first substrate and the second substrate and a low temperature part filler adjacent to a substrate at a side of a low temperature end to discharge heat.

9. The method of claim 8, wherein the first substrate and the second substrate are ceramic substrates.

10. The method of claim 8, wherein the forming the hybrid filler includes:
preparing high temperature part filler material obtained by mixing at least one among zirconium oxide, silicon carbide, a titanium carbide glass fiber and fiber reinforced plastic to parylene or Teflon;
preparing low temperature part filler material obtained by mixing a glass fiber to paraffin or wax; and
forming the hybrid filler by filing the high temperature part filler material and the low temperature part filler material between the joined first and second substrates using a dipping method.

11. The method of claim 8, wherein the forming the hybrid filler includes:
preparing high temperature part filler material obtained by mixing at least one among zirconium oxide, silicon carbide, a titanium carbide glass fiber and fiber reinforced plastic to parylene or Teflon;
preparing low temperature part filler material obtained by mixing a glass fiber to paraffin or wax; and
forming the hybrid filler by coating the high temperature part filler material on the inside surface of the first substrate, the surface of the first electrode and a portion of surface of the thermoelectric device and coating the low temperature part filler material on the inside surface of the second substrate, the surface of the second electrode and a portion of surface of the thermoelectric device using a impregnation method.

12. The method of claim 8, further comprising thermal grease at least one place among between the first substrate and the first electrode, between the second substrate and the second electrode, between the thermoelectric device and the first electrode and between the thermoelectric device and the second electrode.
